(19) United States
(12) Patent Application Publication
(10) Pub. No.: US 2016/0118387 A1
(43) Pub. Date: Apr. 28, 2016

(54) SEMICONDUCTOR DEVICE WITH A BURIED OXIDE STACK FOR DUAL CHANNEL REGIONS AND ASSOCIATED METHODS

(71) Applicant: STMICROELECTRONICS, INC., COPPELL, TX (US)

(72) Inventors: QING LIU, IRVINE, CA (US); NICOLAS LOUBET, GUILDERLAND, NY (US)

(21) Appl. No.: 14/982,037

(22) Filed: Dec. 29, 2015

Related U.S. Application Data
(62) Division of application No. 14/048,244, filed on Oct. 8, 2013.

(51) Int. Cl. H01L 27/092; H01L 29/16; H01L 29/161; H01L 27/12; H01L 29/06

(52) U.S. Cl. CPC H01L 27/0924; H01L 27/1211; H01L 29/0653; H01L 29/161; H01L 29/16

(57) ABSTRACT

A method for making a semiconductor device includes forming a buried oxide stack on a semiconductor wafer. The buried oxide stack includes a first oxide layer, a nitride layer on the first oxide layer, and a second oxide layer on the nitride layer. A semiconductor layer is formed on the second oxide layer. First and second channel regions are formed in the semiconductor layer.

### FIELD OF THE INVENTION

The present invention relates to the field of electronic devices, and more particularly, to semiconductor devices and related methods.

### BACKGROUND

Some semiconductor devices utilize semiconductor-on-insulator (SOI) technology, in which a thin layer of a semiconductor, such as silicon, is separated from a semiconductor substrate by a relatively thick electrically insulating layer. This thick electrically insulating layer is also referred to as a buried oxide (BOX) layer. The semiconductor layer typically has a thickness of a few nanometers, whereas the semiconductor substrate typically has a thickness of a few tens of nanometers.

SOI technology offer certain advantages compared to traditional bulk technology for Complementary Metal Oxide Semiconductor (CMOS) devices. CMOS devices include nMOS transistors and pMOS transistors both formed in the thin silicon layer which overlies the buried oxide (BOX) layer. SOI technology allows CMOS devices to operate at a lower power consumption while providing the same performance level.

Continued CMOS scaling typically requires a fully depleted SOI (FDSOI) device to control short channel effects and to also support transistor operations at lower supply voltages, with low leakage and with reduced transistor threshold voltage variability. The use of silicon germanium (SiGe) as the channel material in an FDSOI device improves pMOSFET performance and enables adjustment of a p-channel device threshold voltage without impacting device performance.

A typical cSiGe integration approach (using condensation techniques) may lead to oxygen penetration through the buried oxide (BOX) layer which in turn oxidizes the underlying semiconductor substrate. As illustrated in FIGS. 1 and 2, a semiconductor device 10 includes a semiconductor substrate 12, a buried oxide (BOX) layer 14 on the semiconductor substrate, and a semiconductor layer 16 on the buried oxide layer. The semiconductor layer 16 includes a PMOS region 20 and an NMOS region 22. A nitride (mask) layer 24 is formed over the NMOS region 22 while a SiGe layer 30 is grown on the PMOS region 20.

A rapid thermal oxidation (RTO) is performed to cause germanium condensation into the PMOS region 20. During the RTO, oxygen also penetrates through the buried oxide layer 14 and oxidizes the underlying semiconductor substrate 12, as represented by arrows 32. This undesirably increases the thickness of the buried oxide layer 14, as indicated by reference 13. This may lead to unwanted stress in the semiconductor substrate 12 and can also affect the back gate efficiency if a thicker oxide is present underneath the PMOS regions.

### SUMMARY

A method for making a semiconductor device comprises forming a buried oxide stack on a semiconductor wafer, with the buried oxide stack comprising a first oxide layer, a nitride layer, and a second oxide layer. The method may further forming a semiconductor layer on the second oxide layer, and forming first and second channel regions in the semiconductor layer.

The semiconductor layer may comprise a first semiconductor material, and forming the first channel region may comprise driving a second semiconductor material into the first semiconductor material. The first semiconductor material may comprise silicon, and the second semiconductor material may comprise silicon and germanium.

Driving the second semiconductor material into the first semiconductor material may comprise forming a second semiconductor layer comprising the second semiconductor material over the first channel region, and oxidizing the second semiconductor layer to drive the second semiconductor material into the first semiconductor material and with the nitride layer blocking further oxidation of the first oxide layer.

The nitride layer advantageously prevents oxygen from penetrating through the second oxide layer to the first oxide layer and to underlying portions of the semiconductor substrate during the oxidizing. Since the semiconductor substrate is not oxidized, a thickness of the first oxide layer remains substantially the same, unwanted stress is not introduced in the semiconductor substrate.

The method may further comprise forming an isolation trench between the first and second channel regions, and forming a dielectric body in the isolation trench. The dielectric body may comprise a nitride liner and an oxide within the nitride liner. The nitride liner advantageously further seals the semiconductor substrate from oxidation.

Another aspect is directed to a semiconductor device comprising a semiconductor substrate, a p-channel metal-oxide semiconductor field-effect transistor (pMOSFET) in the semiconductor substrate, an n-channel metal-oxide semiconductor field-effect transistor (nMOSFET) in the semiconductor substrate, and a shallow trench isolation (STI) region between the pMOSFET and the nMOSFET.

More particularly, the pMOSFET may comprise a first buried oxide stack on the semiconductor substrate. The first buried oxide stack may comprise a first oxide layer, a nitride layer on the first oxide layer, and a second oxide layer on the nitride layer. A first semiconductor layer may be on the first buried oxide stack, and a first pair of source and drain regions may define a p-type channel therebetween in the first semiconductor layer. A first gate may be above the p-type channel.

Similarly, the nMOSFET may comprise a second buried oxide stack on the semiconductor substrate. The second buried oxide stack may comprise a first oxide layer, a nitride layer on the first oxide layer, and a second oxide layer on the nitride layer. A second semiconductor layer may be on the second buried oxide stack, and a second pair of source and drain regions may define an n-type channel therebetween in the second semiconductor layer. A second gate may be above the n-type channel.

### BRIEF DESCRIPTION OF THE DRAWINGS

FIGS. 1-2 are a series of cross-sectional diagrams illustrating an example method of making a semiconductor device in accordance with the prior art.

FIG. 3 is a cross-sectional diagram of a semiconductor device with buried oxide stacks for dual channel regions in accordance with an example embodiment.

FIGS. 4-8 are a series of cross-sectional diagrams illustrating a method of making the semiconductor device of FIG. 3.

FIG. 9 is a cross-sectional view of a FinFET device in accordance with an example embodiment.

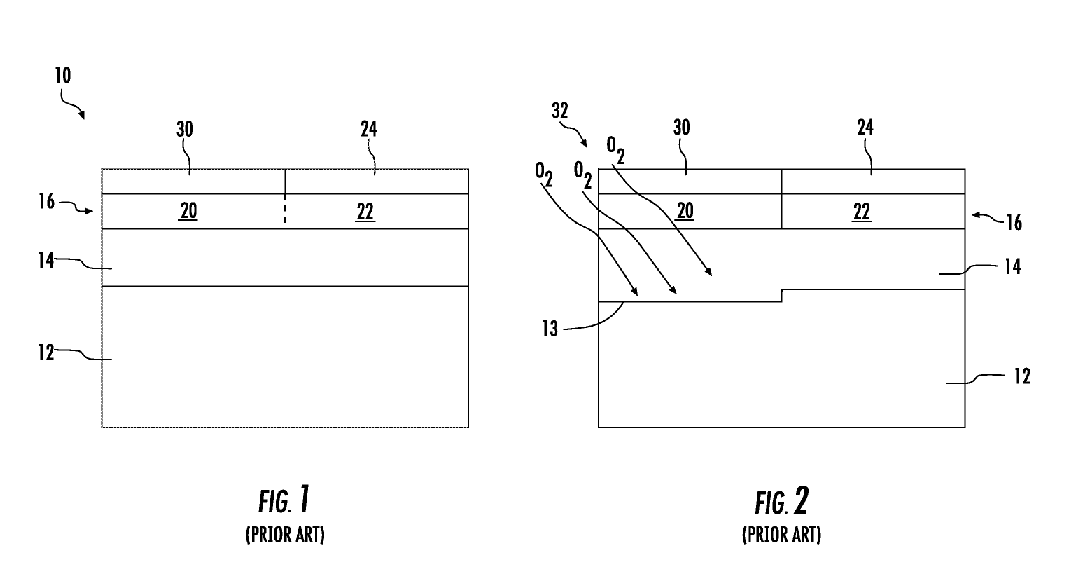

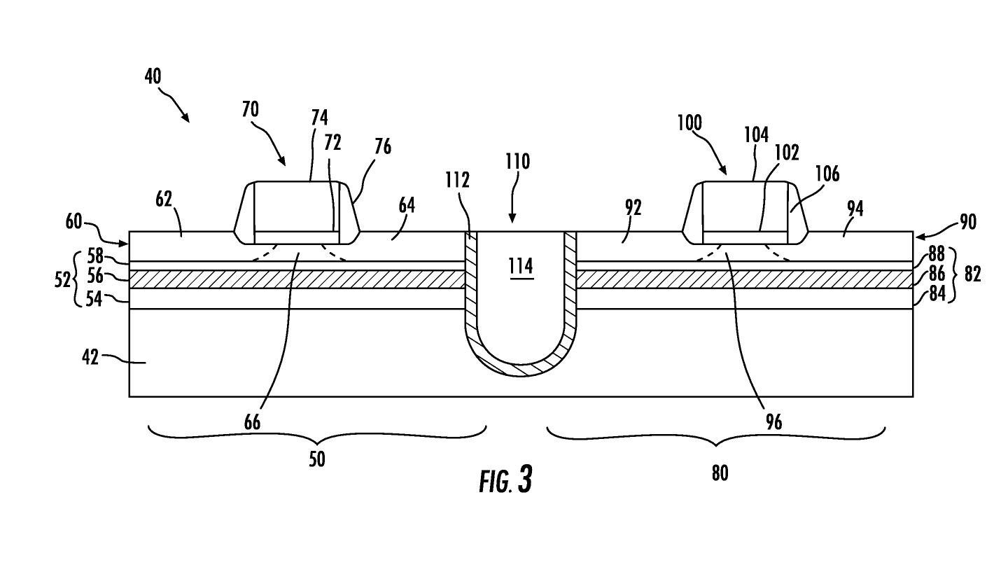

### DETAILED DESCRIPTION OF THE PREFERRED EMBODIMENTS

The present embodiments will now be described more fully hereinafter with reference to the accompanying drawings, in which preferred embodiments are shown. The embodiments may, however, be embodied in many different forms and should not be construed as limited to the embodiments set forth herein. Rather, these embodiments are provided so that this disclosure will be thorough and complete, and will fully convey the scope of the disclosure to those skilled in the art. Like numbers refer to like elements throughout.

Referring initially to FIG. 3, a semiconductor device 40 is first described. In the illustrated embodiment, the semiconductor device 40 is a Complementary Metal Oxide Semiconductor (CMOS) device that includes a p-channel Field Effect transistor (pMOSFET) 50 and an n-channel Field Effect transistor (nMOSFET) 80 on a semiconductor substrate or wafer 42. The pMOSFET 50 and nMOSFET 80 are separated by a shallow trench isolation (STI) region 110.

The pMOSFET 50 includes a first buried oxide stack 52 on the semiconductor substrate 42 and comprises a first oxide layer portion 54, a nitride layer portion 56 on the first oxide layer portion, and a second oxide layer portion 58 on the nitride layer portion. A first semiconductor layer 60 is on the first buried oxide stack 52. A first pair of source and drain regions 62, 64 define a p-type channel region 66 therebetween in the first semiconductor layer 60. A first gate 70 is above the p-type channel region 66. The first gate 70 includes a gate dielectric layer 72, a gate electrode layer 74, and sidewall spacers 76.

In the illustrated embodiment, the first semiconductor layer 60 comprises silicon and germanium, and the semiconductor substrate 42 comprises silicon. When a rapid thermal oxidation (RTO) is performed to form the first semiconductor layer 60, oxygen will typically penetrate into the first buried stack 52.

As will be described in greater detail below, the nitride layer portion 56 in the first buried stack 52 advantageously prevents the oxygen from penetrating through the first oxide layer portion 54 and underlying portions of the semiconductor substrate 42 during the rapid thermal oxidation. Since the semiconductor substrate 42 is not further oxidized, a thickness of the first oxide layer 54 remains substantially the same, unwanted stress is not introduced in the semiconductor substrate. Also, the nitride layer portion 56 has a higher dielectric constant than the oxide layer portions 54 and 58, which makes the semiconductor substrate control (i.e., back gate) more efficient.

Similarly, the nMOSFET 80 includes a second buried oxide stack 82 on the semiconductor substrate 42 and comprises a first oxide layer portion 84, a nitride layer portion 86 on the first oxide layer portion, and a second oxide layer portion 88 on the nitride layer portion. A second semiconductor layer 90 is on the second buried oxide stack 82. A second pair of source and drain regions 92, 94 define an n-type channel region 96 therebetween in the second semiconductor layer 90. A second gate 100 is above the n-type channel region 96. The second gate 100 includes a gate dielectric layer 102, a gate electrode layer 104, and sidewall spacers 106.

In the illustrated embodiment, the second semiconductor layer 90 comprises silicon. While oxidation is not required to form the second semiconductor layer 90, the nitride layer portion 86 in the second buried stack 82 is optional.

The shallow trench isolation (STI) region 110 separating the pMOSFET 50 and nMOSFET 80 includes a dielectric body. The illustrated dielectric body comprises a nitride liner 112 and an oxide 114 within the nitride liner. The nitride liner 112 further isolates the semiconductor substrate 42.

During fabrication of the semiconductor device 40, a wet etching using hydrofluoric acid may be performed. The hydrofluoric acid has a tendency to reduce a thickness of the oxide 114 in the STI region 110. The nitride liner 112 advantageously prevents a short between the source/drain regions 62, 64, 92, 94 and the semiconductor substrate 42 should the thickness of the oxide 114 be reduced too much.

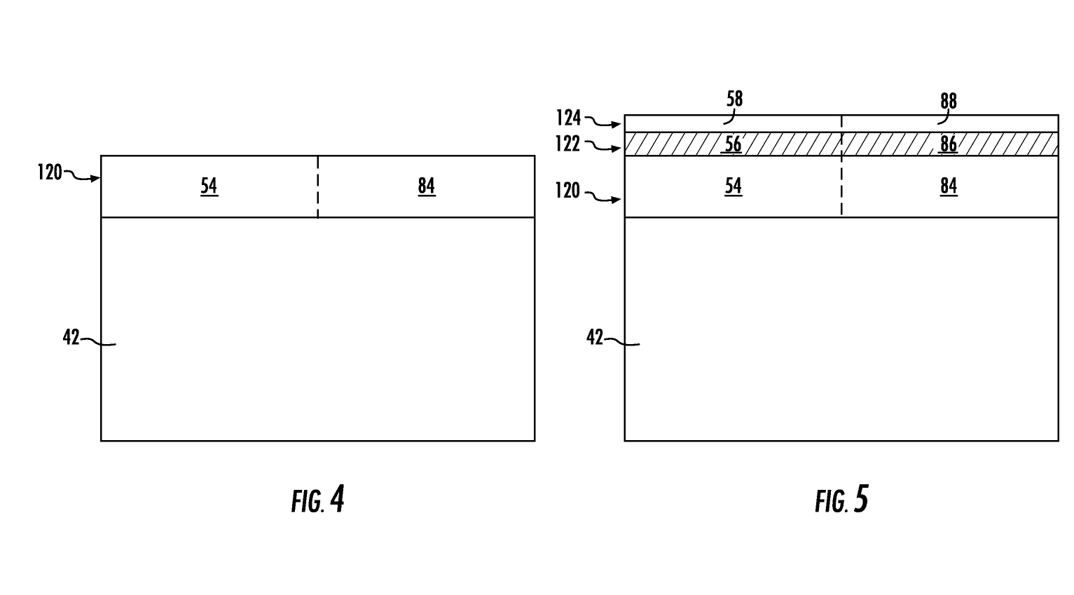

A method for making the semiconductor device 40 is now described with reference to FIGS. 4-8. Starting with the semiconductor substrate or wafer 42, a first oxide layer 120 is formed thereon, as illustrated in FIG. 4. A thickness of the first oxide layer 120 may be within a range of about 5 to 15 nm. The left half of the first oxide layer 120 defines the first oxide layer portion 54, whereas the right half of the first oxide layer 120 defines the first oxide layer portion 84.

A nitride layer 122 is then formed on the first oxide layer 120, and a second oxide layer 124 is formed on the nitride layer, as illustrated in FIG. 5. A thickness of the nitride layer 122 may be within a range of about 2 to 4 nm, and a thickness of the second oxide layer 124 may also be within a range of about 2 to 4 nm. A high temperature anneal may be used to densify the nitride layer 122 and the second oxide layer 124.

The left half of the nitride layer 122 defines the nitride layer portion 56, whereas the right half of the nitride layer defines the nitride layer portion 86. Similarly, the left half of the second oxide layer 124 defines the second oxide layer portion 58, whereas the right half of the second oxide layer defines the second oxide layer portion 88.

The first oxide layer portion 54, the nitride layer portion 56 and the second oxide layer portion 58 form the first buried oxide stack 52 for the pMOSFET 50. The first oxide layer portion 84, the nitride layer portion 86 and the second oxide layer portion 88 form the second buried oxide stack 82 for the nMOSFET 80.

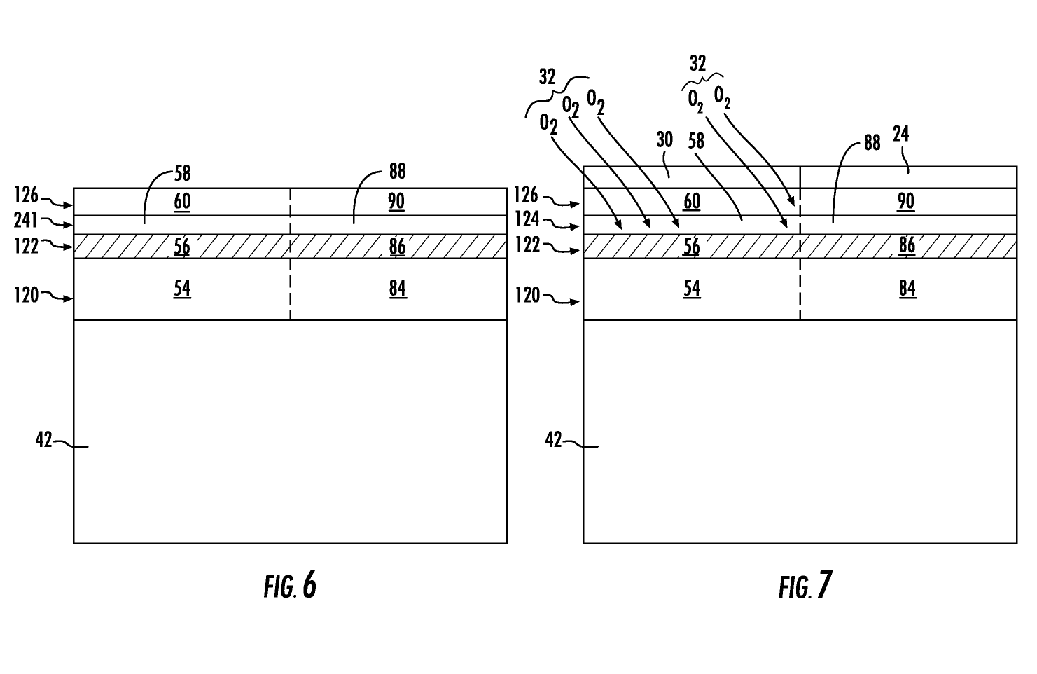

A semiconductor layer 126 is then formed on the first and second buried oxide stacks 52 and 82, as illustrated in FIG. 6. A thickness of the semiconductor layer 126 may be within a range of about 6 to 8 nm. The left half of the semiconductor layer 126 defines the first semiconductor layer 60, whereas the right half of the semiconductor layer 126 defines the second semiconductor layer 90.

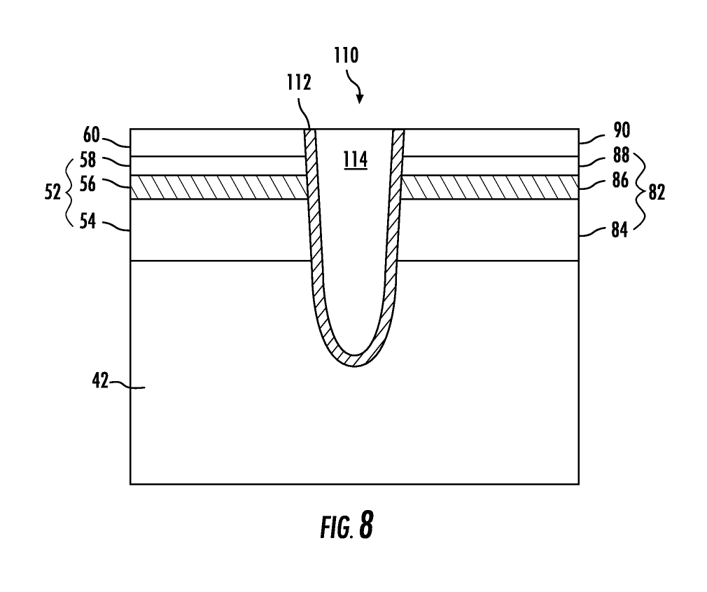

To form the first semiconductor layer 60, a hard mask 24 is placed over the second semiconductor layer 90, as illustrated in FIG. 7. Silicon germanium 30 is epitaxially grown over the first semiconductor layer 60. A rapid thermal oxidation (RTO) is performed to cause germanium condensation into the first semiconductor layer 60, as represented by arrows 32. During the oxidation, the nitride layer portion 56 in the first buried oxide stack 52 blocks the oxygen from reaching the underlying portions of the semiconductor substrate 42. The first semiconductor layer 60 may now have a concentration of about 40% germanium, although other concentrations may be used, as readily appreciated by those skilled in the art.

The nitride layer portion 56 advantageously prevents oxygen from penetrating through to the first oxide layer portion 54 and to the semiconductor substrate 42 during the oxidizing. Since the semiconductor substrate or wafer 42 is not oxidized, a thickness of the first oxide layer 54 remains substantively the same, unwanted stress is not introduced in the semiconductor substrate 42.

After formation of the first semiconductor layer 60, the shallow trench isolation (STI) region 110 is formed, as illustrated in FIG. 8. Alternatively, forming the STI region 110 may be performed before the first semiconductor layer 60 is formed. The STI region 110 includes a dielectric body that include the nitride liner 112 and the oxide 114 within the nitride liner. A thickness of the nitride liner 112 may be within a range of about 3 to 9 nm. The nitride liner 112 further isolates the semiconductor substrate 42.

Further process steps are performed to provide the remaining structure as illustrated in FIG. 3, as readily appreciated by those skilled in the art.

In view of the above, a variety of different transistor structures may be implemented, including but not necessarily limited to: planar CMOS, high-k metal gate CMOS, PD-SOI, FD-SOI, UTBB, vertical double gate, buried gate, FinFET, tri-gate, multi-gate, 2D, 3D, raised source/drain, strained source/drain, strained channel, and combinations/hybrids thereof, for example.

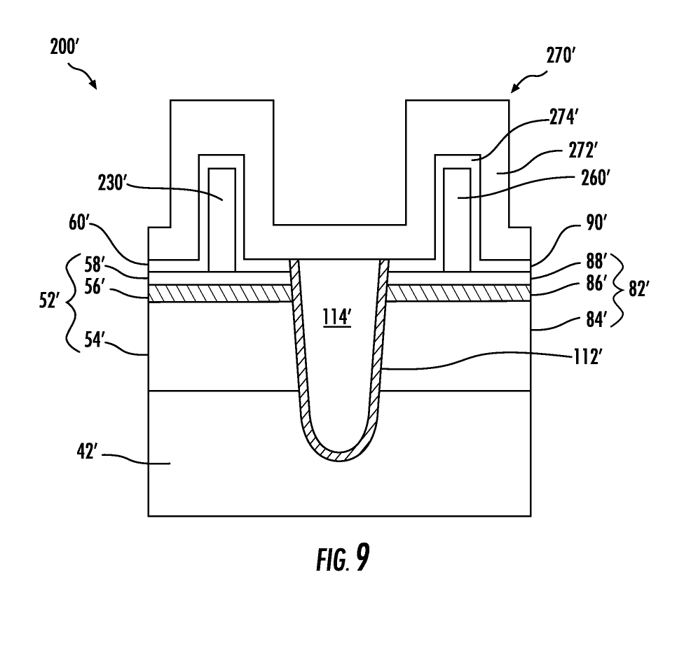

A cross-sectional view of a FinFET device 200′ is illustrated in FIG. 9. The FinFET device 200′ includes a semiconductor substrate or wafer 42′ having a pMOSFET including a first buried oxide stack 52′ on the semiconductor substrate 42′ and comprises a first oxide layer portion 54′, a nitride layer portion 56′ on the first oxide layer portion, and a second oxide layer portion 58′ on the nitride layer portion. A first semiconductor layer 60′ is on the first buried oxide stack 52. Similarly, the FinFET device 200′ an nMOSFET including a second buried oxide stack 82′ on the semiconductor substrate 42′ and comprises a first oxide layer portion 84′, a nitride layer portion 86′ on the second oxide layer portion, and a second oxide layer portion 88′ on the nitride layer portion. A second semiconductor layer 90′ is on the second buried oxide stack 82′.

A fin 230′ defines the channel for the nMOSFET, and a fin 260′ defines the channel for the pMOSFET. A gate 270′ overlies the fins 230′, 260′ and includes a polysilicon layer 272′ on a dielectric layer 274′.

The FinFET device 200′ includes raised source/drain regions, which may be epitaxially grown. Epitaxially grown SiGe may be used in reducing resistance and stress of the source/drain regions. This aspect of the source/drain regions is also applicable to FD-SOI.

Many modifications and other embodiments will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1-17. (canceled)

18. A semiconductor device comprising:
a semiconductor substrate;
a p-channel metal-oxide semiconductor field-effect transistor (pMOSFET) comprising
a first buried oxide stack on said semiconductor substrate and comprising a first oxide layer, a nitride layer on said first oxide layer, and a second oxide layer on said nitride layer,
a first semiconductor layer on said first buried oxide stack,
a first pair of source and drain regions defining a p-type channel therebetween in said first semiconductor layer, and
a first gate above the p-type channel;
an n-channel metal-oxide semiconductor field-effect transistor (nMOSFET) comprising
a second buried oxide stack on said semiconductor substrate and comprising a first oxide layer, a nitride layer on said first oxide layer, and a second oxide layer on said nitride layer,
a second semiconductor layer on said second buried oxide stack,
a second pair of source and drain regions defining an n-type channel therebetween in said second semiconductor layer, and
a second gate above the n-type channel; and
a shallow trench isolation (STI) region between said p-channel metal-oxide semiconductor field-effect transistor and said n-channel metal-oxide semiconductor field-effect transistor, said STI region extending through the buried oxide stack and into the semiconductor substrate.

19. The semiconductor device according to claim 18 wherein the first semiconductor layer comprises silicon and germanium, and the second semiconductor layer comprises silicon.

20. The semiconductor device according to claim 18 wherein said STI region comprises a dielectric body.

21. The semiconductor device according to claim 20 wherein the dielectric body comprises a nitride liner and an oxide within the nitride liner.

22. The semiconductor device according to claim 18 wherein each of said pMOSFET and said nMOSFET has a FinFET structure.

23. The semiconductor device according to claim 18 wherein each of said pMOSFET and said nMOSFET has a lateral structure.

24. The semiconductor device according to claim 21 wherein the nitride liner has a thickness in a range of 3 to 9 nm.

25. The semiconductor device according to claim 18 wherein the first oxide layer has a thickness in a range of 5 to 15 nm.

26. The semiconductor device according to claim 18 wherein the nitride layer has a thickness in a range of 2 to 4 nm.

27. The semiconductor device according to claim 18 wherein the second oxide layer has a thickness in a range of 2 to 4 nm.

28. The semiconductor device according to claim 18 wherein the first and second semiconductor layers each has a thickness in a range of 6 to 8 nm.

29. A semiconductor device comprising:
a semiconductor substrate;
a p-channel metal-oxide semiconductor field-effect transistor (pMOSFET) having a finFET structure and comprising
a first buried oxide stack on said semiconductor substrate and comprising a first oxide layer, a nitride layer on said first oxide layer, and a second oxide layer on said nitride layer,
a first semiconductor layer on said first buried oxide stack and comprising silicon,
a first pair of source and drain regions defining a p-type channel therebetween in said first semiconductor layer, and
a first gate above the p-type channel;
an n-channel metal-oxide semiconductor field-effect transistor (nMOSFET) having a finFET structure and comprising
a second buried oxide stack on said semiconductor substrate and comprising a first oxide layer, a nitride layer on said first oxide layer, and a second oxide layer on said nitride layer,
a second semiconductor layer on said second buried oxide stack and comprising silicon and germanium,
a second pair of source and drain regions defining an n-type channel therebetween in said second semiconductor layer, and
a second gate above the n-type channel; and
a shallow trench isolation (STI) region between said p-channel metal-oxide semiconductor field-effect transistor and said n-channel metal-oxide semiconductor field-effect transistor, said STI region extending through the buried oxide stack and into the semiconductor substrate.

30. The semiconductor device according to claim 29 wherein said STI region comprises a dielectric body.

31. The semiconductor device according to claim 30 wherein the dielectric body comprises a nitride liner and an oxide within the nitride liner.

32. The semiconductor device according to claim 31 wherein the nitride liner has a thickness in a range of 3 to 9 nm.

33. The semiconductor device according to claim 29 wherein the first oxide layer has a thickness in a range of 5 to 15 nm.

34. The semiconductor device according to claim 29 wherein the nitride layer has a thickness in a range of 2 to 4 nm.

35. The semiconductor device according to claim 29 wherein the second oxide layer has a thickness in a range of 2 to 4 nm.

36. The semiconductor device according to claim 29 wherein the first and second semiconductor layers each has a thickness in a range of 6 to 8 nm.

37. A semiconductor device comprising:
a semiconductor substrate;
a p-channel metal-oxide semiconductor field-effect transistor (pMOSFET) having a lateral structure and comprising
a first buried oxide stack on said semiconductor substrate and comprising a first oxide layer, a nitride layer on said first oxide layer, and a second oxide layer on said nitride layer,
a first semiconductor layer on said first buried oxide stack and comprising silicon,
a first pair of source and drain regions defining a p-type channel therebetween in said first semiconductor layer, and
a first gate above the p-type channel;
an n-channel metal-oxide semiconductor field-effect transistor (nMOSFET) having a lateral structure and comprising
a second buried oxide stack on said semiconductor substrate and comprising a first oxide layer, a nitride layer on said first oxide layer, and a second oxide layer on said nitride layer,
a second semiconductor layer on said second buried oxide stack and comprising silicon and germanium,
a second pair of source and drain regions defining an n-type channel therebetween in said second semiconductor layer, and
a second gate above the n-type channel; and
a shallow trench isolation (STI) region between said p-channel metal-oxide semiconductor field-effect transistor and said n-channel metal-oxide semiconductor field-effect transistor, said STI region extending through the buried oxide stack and into the semiconductor substrate.

38. The semiconductor device according to claim 37 wherein said STI region comprises a dielectric body.

39. The semiconductor device according to claim 38 wherein the dielectric body comprises a nitride liner and an oxide within the nitride liner.

40. The semiconductor device according to claim 39 wherein the nitride liner has a thickness in a range of 3 to 9 nm.

41. The semiconductor device according to claim 37 wherein the first oxide layer has a thickness in a range of 5 to 15 nm.

42. The semiconductor device according to claim 37 wherein the nitride layer has a thickness in a range of 2 to 4 nm.

43. The semiconductor device according to claim 37 wherein the second oxide layer has a thickness in a range of 2 to 4 nm.

44. The semiconductor device according to claim 37 wherein the first and second semiconductor layers each has a thickness in a range of 6 to 8 nm.
